(19) United States
(12) Patent Application Publication
(10) Pub. No.: US 2026/0088531 A1
(43) Pub. Date: Mar. 26, 2026

(54) HIGH POWER WIRE CONNECTION TO PRINTED CIRCUIT BOARD

(71) Applicant: Steering Solutions IP Holding Corporation, Saginaw, MI (US)

(72) Inventors: Daniel J. Klenk, Saginaw, MI (US); Delynn M. Streng, Freeland, MI (US); Steven J. Collier-Hallman, Frankenmuth, MI (US)

(21) Appl. No.: 18/890,915

(22) Filed: Sep. 20, 2024

(51) Int. Cl. H01R 12/57; H01R 12/53; H05K 1/02; H05K 1/18

(52) U.S. Cl. CPC H01R 12/57; H01R 12/53; H05K 1/0263; H05K 1/181; H01R 2201/26; H05K 2201/10265; H05K 2201/10287

(57) ABSTRACT

A printed circuit board assembly for a vehicle steering system includes a printed circuit board. The printed circuit board assembly also includes a terminal operatively mounted to a surface of the printed circuit board, wherein the terminal is formed of an elastically deformable material, wherein the terminal includes a first spring segment and a second spring segment. The printed circuit board assembly further includes a wire disposed between, and in contact with, the first spring segment and the second spring segment.

### FIELD OF THE INVENTION

The embodiments described herein relate to electrical terminals and, more particularly, to a high power wire connection to a printed circuit board.

### BACKGROUND

A vehicle, such as a car, truck, sport utility vehicle, crossover, mini-van, marine craft, aircraft, all-terrain vehicle, recreational vehicle, or other suitable vehicles, typically include various electric motor-vehicle interface locations. Electric motors may be used throughout the vehicle for a variety of functions, such as power steering, steering column adjustment, and other functionalities. These motors typically receive instructions from a circuit board assembly that facilitates the motor-vehicle interface. Circuit boards (e.g., a printed circuit board) locate and connect various electronic components and thus design and packaging considerations are important for end-use.

Electrical interfaces for a terminal to wire connection typically requires welding in high current automotive applications. For example, 30 A continuous current with 140 A short durations may be required. Demands and design considerations for such high power applications differ from those of home electronics with 15 A currents. The automotive industry uses spring contacts for terminal-to-terminal applications, but they are not used for wire-to-terminal applications.

### SUMMARY

According to one aspect of the disclosure, a printed circuit board assembly for a vehicle steering system includes a printed circuit board. The printed circuit board assembly also includes a terminal operatively mounted to a surface of the printed circuit board, wherein the terminal is formed of an elastically deformable material, wherein the terminal includes a first spring segment and a second spring segment. The printed circuit board assembly further includes a wire disposed between, and in contact with, the first spring segment and the second spring segment.

According to another aspect of the disclosure, a printed circuit board assembly for a vehicle steering system includes a printed circuit board. The printed circuit board assembly also includes a shroud defining a recess having a terminal fixed within the recess, wherein the terminal includes a first spring segment and a second spring segment. The printed circuit board assembly further includes a wire extending from the printed circuit board and disposed between, and in contact with, the first spring segment and the second spring segment.

According to yet another aspect of the disclosure, a printed circuit board assembly for a vehicle steering system includes a printed circuit board. The printed circuit board assembly also includes a terminal operatively mounted to a surface of the printed circuit board, wherein the terminal is formed of an elastically deformable material. The printed circuit board assembly further includes a shroud formed of plastic, wherein the shroud includes a base, a first leg and a second leg, wherein the first leg and the second leg extend away from the base of the shroud toward the printed circuit board. The printed circuit board assembly yet further includes a wire operatively coupled to the shroud and disposed between, and in contact with, the terminal.

These and other advantages and features will become more apparent from the following description taken in conjunction with the drawings.

### BRIEF DESCRIPTION OF THE DRAWINGS

The subject matter that is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 is a perspective view of a printed circuit board with various wire-to-terminal connections;

FIG. 2 is a perspective view of a wire being connected to a terminal of the printed circuit board in a first assembly position of the wire;

FIG. 3 is a perspective view of the wire being connected to the terminal of the printed circuit board in a second assembly position of the wire;

FIG. 4 illustrates a wire being connected to a terminal in a first assembly position according to another aspect of the disclosure; and

FIG. 5 illustrates the wire being connected to the terminal of FIG. 4 in a second assembly position.

### DETAILED DESCRIPTION

The following discussion is directed to various embodiments of the disclosure. Although one or more of these embodiments may be discussed and/or illustrated in more detail than others, the embodiments disclosed should not be interpreted, or otherwise used, as limiting the scope of the disclosure, including the claims. In addition, one skilled in the art will understand that the following description has broad application, and the discussion of any embodiment is meant only to be illustrative of that embodiment, and not intended to intimate that the scope of the disclosure, including the claims, is limited to that embodiment.

As described, a vehicle, such as a car, truck, sport utility vehicle, crossover, mini-van, marine craft, aircraft, all-terrain vehicle, recreational vehicle, or other suitable vehicles, typically include various motor-vehicle interface locations. The motors described herein may be used throughout the vehicle for a variety of functions, such as power steering, steering column adjustment, and other functionalities. The electrically powered applications require circuit boards having a variety of electrical connections. The embodiments disclosed herein provide a more robust electrical terminal for such connections.

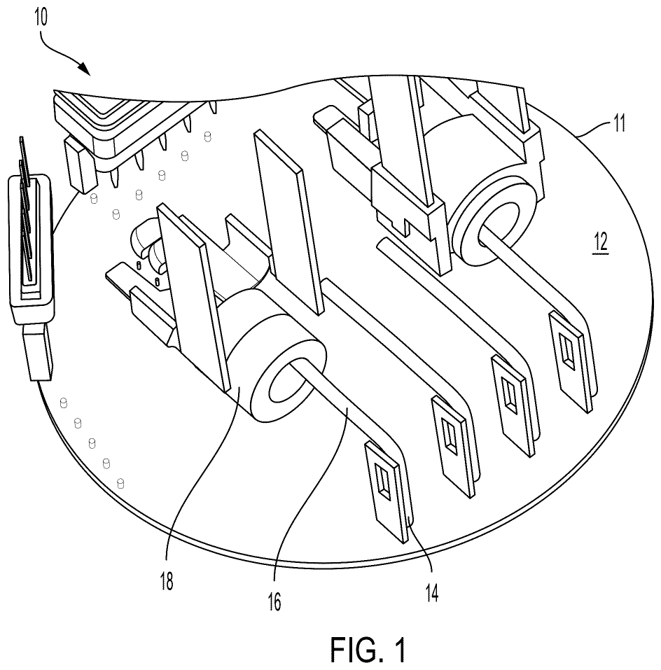

Referring now to FIG. 1, a portion of a printed circuit board assembly is shown and is generally referenced with numeral 10. The printed circuit board assembly 10 includes a printed circuit board 11 having a board surface 12. The board surface has various electronic components electrically connected thereto. As shown, one or more terminals 14 are mounted to the board surface 12 of the printed circuit board 11 and extend away from the board surface 12. For each terminal 14, an electrical wire 16 may be connected thereto to establish an electrical connection between an electronic component 18 and the printed circuit board 11. It is to be appreciated that the electronic component 18 being connected to the printed circuit board 11 with the wire 16 may be various electronic components which may be commonly used in vehicle steering applications.

The embodiments disclosed herein facilitate an electrical connection interface with large surface contact area and high contact force which is capable of carrying high current without overheating the contact. For example, a high powered connection, as used herein, refers to a connection capable of carrying a current of 30 amps—or more—continuously and 140 amps—or more—for short durations. This is greater than home electronics and allows for a higher DC current and for a direct connection between the wire 16 and the printed circuit board 11.

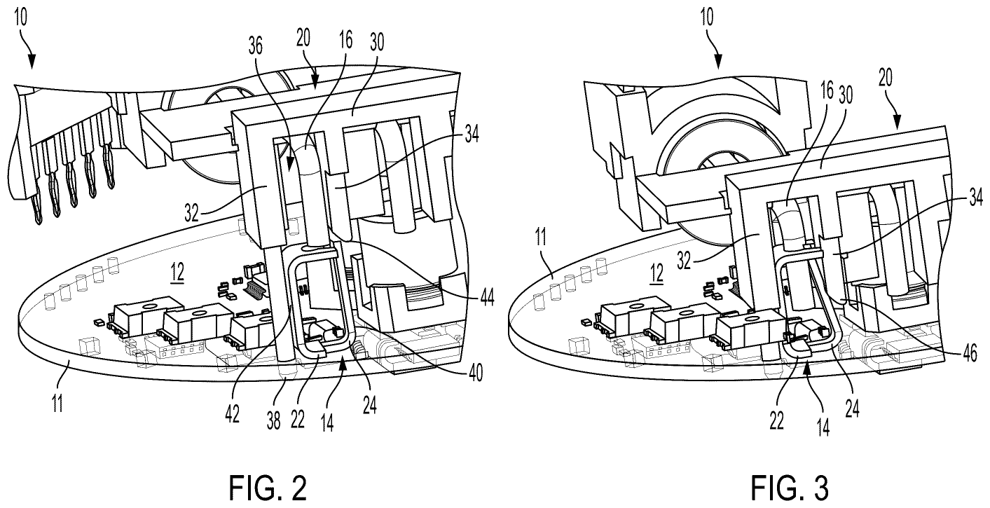

Referring now to FIGS. 2 and 3, the electric connection between the wire 16 and the printed circuit board 11 via the terminal 14 is shown in greater detail.

The terminal 14, according to the embodiment shown in FIGS. 2 and 3, includes a first spring segment 22 and a second spring segment 24. In some embodiments, the first spring segment 22 and the second spring segment 24 are completely separate components, while other embodiments may include a unitary member with a base connecting the two spring segments 22, 24. The terminal 14 is soldered to the board surface 12 of the printed circuit board 11 and serves as an interface between the wire 16 and the printed circuit board 11 in an assembled condition of the printed circuit board assembly 10. The terminal 14 is formed of any suitable material having elastic deformation properties. For example, the first spring segment 22 and the second spring segment 24 may be formed of spring steel or any other material suitable to have the spring segments 22, 24 return to their initial state when not biased away from the initial state position.

A shroud 20 is operatively coupled to the wire 16 and the electronic component 18, which are to be connected to the terminal 14. The shroud 20 is formed of plastic in some embodiments. The shroud 20 the shroud includes a base 30, a first leg 32, and a second leg 34. The first leg 32 and the second leg 34 extend away from the base 30 of the shroud 20 toward the board surface 12 of the printed circuit board 11. In the illustrated orientation of FIGS. 2 and 3, the first leg 32 and the second leg 34 extend downwardly away from the base 30 toward the board surface 12. The first leg 32 and the second leg 34 define a gap 36 therebetween. The first spring segment 22 and the second spring segment 24 are located within the gap 36 between the first leg 32 and the second leg 34 when the printed circuit board assembly 10 is assembled, as shown in FIG. 3. The wire 16 is disposed between the first leg 32 and the second leg 34.

The first leg 32 extends away from the base 30 to a first leg distal tip 38 to define a first leg length between the base 30 and the first leg distal tip 38. Similarly, the second leg 34 extends away from the base 30 to a second leg distal tip 40 to define a second leg length between the base 30 and the second leg distal tip 40. As shown, the first leg length is greater than the second leg length. The relative leg length (i.e., longer first leg length) ensures that the first leg distal tip 38 reaches the terminal 14 prior to the second leg distal tip 40 reaching the terminal 14 since the terminal 14 extends to a substantially uniform distance from the board surface 12 of the printed circuit board 11. The first leg 32 and the second leg 34 are spaced to position the legs 32, 34 on outer edges 42, 44, respectively, of the first spring segment 22 and the second spring segment 24 as the shroud 20, and consequently the wire 16, are moved closer to the board surface 12.

During assembly, the shroud 20 is moved closer to the board surface 12 and the first leg 32 slides along the outer edge 42 of the first spring segment 22. The first leg 32 is substantially rigid and does not allow the first spring segment 22 to be biased outwardly as the wire 16 is inserted into contact with the terminal 14. Meanwhile, the second leg 34 subsequently (relative to the first leg 32 contact with the first spring segment 22) contacts the second spring segment 24 as the shroud 20 is moved closer to the board surface 12. Contact between the second leg 34 and the second spring segment 24 biases the elastically deformable, and resilient, second spring segment 24 toward the wire 16 to promote more contact between the terminal 14 and the wire 16. In some embodiments, the second leg distal tip 40 includes an angled end 46 to assist with the initial contact between the second leg 34 and the second spring segment 24 for smooth insertion.

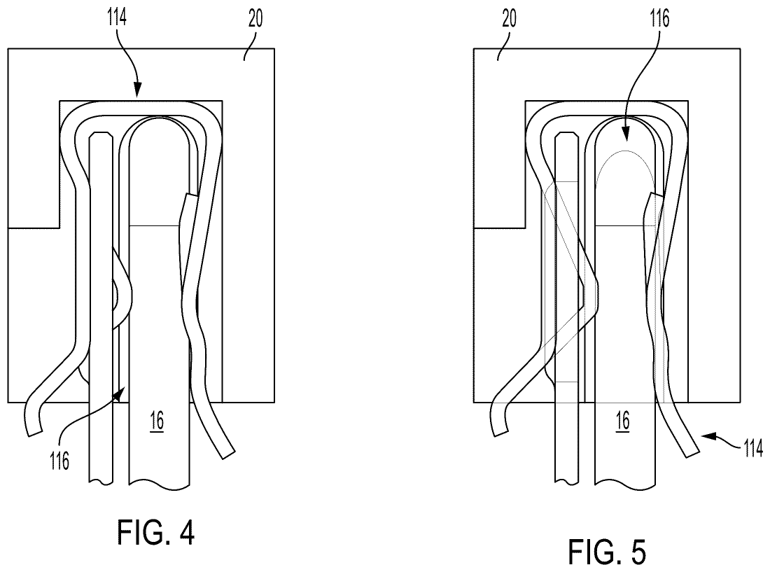

Referring now to FIGS. 4 and 5, another embodiment of the printed circuit board assembly 10 is illustrated. In particular, a portion of the interface between the wire 16 and a terminal 114 is shown. In the illustrated embodiment, the terminal 114 is fixedly secured within a recess 116 defined by the shroud 20, with the wire 16 operatively coupled to the board surface 12 of the printed circuit board 11. In the illustrated embodiment, the wire 16 extends away from the board surface 12 and is slid within the terminal 114 of the shroud 20. The terminal 114 is a clip or other spring-like device which is prevented from moving outwardly by walls which define the recess 116. In some embodiments, the terminal 114 is the structure described above in connection with the embodiments of FIGS. 2 and 3. However, any suitable structure with elastically deformable segments for contacting the wire 16 is contemplated.

While the invention has been described in detail in connection with only a limited number of embodiments, it is to be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Moreover, any feature, element, component or advantage of any one embodiment can be used on any of the other embodiments. Accordingly, the invention is not to be seen as limited by the foregoing description.

What is claimed is:

1. A printed circuit board assembly for a vehicle steering system comprising:
a printed circuit board;
a terminal operatively mounted to a surface of the printed circuit board, wherein the terminal is formed of an elastically deformable material, wherein the terminal includes a first spring segment and a second spring segment; and
a wire disposed between, and in contact with, the first spring segment and the second spring segment.

2. The printed circuit board assembly of claim 1, wherein the wire is operatively coupled to a shroud.

3. The printed circuit board assembly of claim 2, wherein the shroud is formed of plastic.

4. The printed circuit board assembly of claim 2, wherein the shroud includes a base, a first leg and a second leg, wherein the first leg and the second leg extend away from the base of the shroud toward the printed circuit board.

5. The printed circuit board assembly of claim 4, wherein the first leg extends away from the base to a first leg distal tip to define a first leg length, wherein the second leg extends away from the base to a second leg distal tip to define a second leg length, wherein the first leg length is greater than the second leg length.

6. The printed circuit board assembly of claim 5, wherein the first leg and the second leg define a gap therebetween, wherein the first spring segment and the second spring segment are located between the first leg and the second leg.

7. The printed circuit board assembly of claim 6, wherein the second leg biases the second spring segment toward the wire and the first spring segment.

8. The printed circuit board assembly of claim 5, wherein the second leg distal tip includes an angled end.

9. The printed circuit board assembly of claim 1, wherein the terminal electrically connects the wire and the printed circuit board with a current of at least 30 Amps.

10. A printed circuit board assembly for a vehicle steering system comprising:
a printed circuit board;
a shroud defining a recess having a terminal fixed within the recess, wherein the terminal includes a first spring segment and a second spring segment; and
a wire extending from the printed circuit board and disposed between, and in contact with, the first spring segment and the second spring segment.

11. The printed circuit board assembly of claim 10, wherein the shroud is formed of plastic.

12. The printed circuit board assembly of claim 10, wherein the terminal electrically connects the wire and the printed circuit board with a current of at least 30 Amps.

13. A printed circuit board assembly for a vehicle steering system comprising:
a printed circuit board;
a terminal operatively mounted to a surface of the printed circuit board, wherein the terminal is formed of an elastically deformable material;
a shroud formed of plastic, wherein the shroud includes a base, a first leg and a second leg, wherein the first leg and the second leg extend away from the base of the shroud toward the printed circuit board; and
a wire operatively coupled to the shroud and disposed between, and in contact with, the terminal.

14. The printed circuit board assembly of claim 13, wherein the terminal includes a first spring segment and a second spring segment.

15. The printed circuit board assembly of claim 14, wherein the first leg extends away from the base portion to a first leg distal tip to define a first leg length, wherein the second leg extends away from the base portion to a second leg distal tip to define a second leg length, wherein the first length is greater than the second length.

16. The printed circuit board assembly of claim 15, wherein the first leg and the second leg define a gap therebetween, wherein the first spring segment and the second spring segment are located between the first leg and the second leg.

17. The printed circuit board assembly of claim 16, wherein the second leg biases the second spring segment toward the wire and the first spring segment.

18. The printed circuit board assembly of claim 15, wherein the second leg distal tip includes an angled end.

19. The printed circuit board assembly of claim 13, wherein the terminal electrically connects the wire and the printed circuit board with a current of at least 30 Amps.
